(19) United States
(12) Patent Application Publication
(10) Pub. No.: US 2025/0329627 A1
(43) Pub. Date: Oct. 23, 2025

(54) SEMICONDUCTOR DEVICE PACKAGE AND METHODS OF MANUFACTURE

(71) Applicant: SEMICONDUCTOR COMPONENTS INDUSTRIES, LLC, Scottsdale, AZ (US)

(72) Inventors: Sixin JI, NanTong (CN); Keunhyuk LEE, Suzhou (CN); Jie CHANG, Suzhou (CN); XiaoYing YUAN, Suzhou (CN); AnAn XING, Suzhou (CN)

(73) Assignee: SEMICONDUCTOR COMPONENTS INDUSTRIES, LLC, Scottsdale, AZ (US)

(21) Appl. No.: 18/638,568

(22) Filed: Apr. 17, 2024

(51) Int. Cl. H01L 23/498; H01L 23/00; H01L 23/31; H01L 23/373

(52) U.S. Cl. CPC H01L 23/49844; H01L 23/3107; H01L 23/3735; H01L 24/32; H01L 24/48; H01L 24/73; H01L 24/83; H01L 2224/32245; H01L 2224/48175; H01L 2224/73265; H01L 2224/8384; H01L 2924/1815

(57) ABSTRACT

In a general aspect, a semiconductor device package includes a ceramic substrate having a first surface and a second surface opposite the first surface, a first metal layer disposed on the first surface of the ceramic substrate, a second metal layer disposed on the second surface of the ceramic substrate, and a semiconductor die having a first surface and a second surface opposite the first surface. The first surface of the semiconductor die is coupled with the first metal layer via first sintering material. The semiconductor device package also includes a first signal lead coupled with the second surface of the semiconductor die via second sintering material, a second signal lead coupled with the second surface of the semiconductor die via third sintering material; and a third signal lead coupled with the first metal layer via a weld.

### TECHNICAL FIELD

This description relates to electronic device assemblies. More specifically, this description relates to semiconductor device packages.

### BACKGROUND

Solder can be used to physically and/or electrically attach elements of a semiconductor device package with one another. Electrical solder can, however, contain hazardous substances such as lead, which can result in such devices failing to meet Restriction of Hazardous Substances (RoHS) requirements. In order to comply with RoHS requirements, sintering material, such as silver (Ag) sinter, can be used for such attachments. However, in discrete semiconductor device packages, such as packages with a single semiconductor die (e.g., a power transistor), use of sintering material, such as for attachment of a semiconductor die to a bare copper leadframe, can lead to reliability issues, such as cracking of the sintering material layer as a result of thermal cycling reliability testing. Such cracking can result in degradation of thermal dissipation performance due to increased thermal resistance and/or degradation of electrical performance due to increased electrical resistance.

### SUMMARY

In a general aspect, a semiconductor device package includes a ceramic substrate having a first surface and a second surface opposite the first surface, a first metal layer disposed on the first surface of the ceramic substrate, a second metal layer disposed on the second surface of the ceramic substrate, and a semiconductor die having a first surface and a second surface opposite the first surface. The first surface of the semiconductor die is coupled with the first metal layer via first sintering material. The semiconductor device package also includes a first signal lead coupled with the second surface of the semiconductor die via second sintering material, a second signal lead coupled with the second surface of the semiconductor die via third sintering material; and a third signal lead coupled with the first metal layer via a weld.

In another general aspect, a semiconductor device package includes a ceramic substrate having a first surface and a second surface opposite the first surface, a first metal layer disposed on the first surface of the ceramic substrate, a second metal layer disposed on the second surface of the ceramic substrate, and a semiconductor die having a first surface and a second surface opposite the first surface. The first surface of the semiconductor die is coupled with the first metal layer via first sintering material. The semiconductor device package also includes a first signal lead coupled with the second surface of the semiconductor die via second sintering material, a second signal lead coupled with the second surface of the semiconductor die via a first bond wire, and a third signal lead coupled with the first metal layer via a weld.

In another general aspect, a method for producing a semiconductor device package includes disposing first sintering material on a metal layer, the metal layer being disposed on a ceramic substrate. The method also includes disposing a first surface of a semiconductor die on the first sintering material, and disposing second sintering material on a second surface of the semiconductor die, the second surface being opposite the first surface. The method further includes disposing a first signal lead on the second sintering material; performing a sintering operation to couple the first surface of the semiconductor die with the metal layer and to couple the first signal lead to the second surface of the semiconductor die. The method also further includes welding a second signal lead to the metal layer.

### BRIEF DESCRIPTION OF THE DRAWINGS

FIG. 1 is a diagram schematically illustrating a side view of an example semiconductor device package.

FIG. 2 is a diagram schematically illustrating a side view of another example semiconductor device package with an attached heatsink.

FIG. 3 is a diagram schematically illustrating an example creepage path of the semiconductor device package of FIG. 2.

FIG. 4 is a diagram illustrating an example semiconductor device package, which can be an implementation of the semiconductor device packages of FIGS. 1 to 3.

FIGS. 5A to 5D are diagrams illustrating example signal leads that can be included in a semiconductor device package.

FIG. 6 is a diagram illustrating a manufacturing process for producing a semiconductor device package.

FIG. 7 is a diagram illustrating another manufacturing process for producing a semiconductor device package.

### DETAILED DESCRIPTION

At least one technical problem with previous semiconductor device packages is cracking of sintering material, such as Ag sinter used to couple a semiconductor die with a bare copper die attach paddle. Such cracking can occur as a result of thermal cycling (e.g., during reliability testing and/or operation of the semiconductor device. For instance, such cracking can occur due to mismatch in coefficients of thermal expansion (CTEs) of copper (e.g., of a die attach paddle of a bare copper leadframe) and material of the semiconductor die, such as a silicon carbide (SiC) semiconductor die. For instance, copper has a CTE of 17 parts-per-million per degree-Kelvin (ppm/K), while SiC has a CTE of 3-5 ppm/K. This mismatch in CTEs results in stress, during thermal cycling, on sintering material used to couple the semiconductor die to the copper die attach paddle, which can cause the sintering material to crack, with the amount cracking and size of associate cracks increasing over time, leading to degradation in thermal dissipation performance and/or electrical performance.

One technical solution to the aforementioned technical problem can be to reduce CTE mismatch between a semiconductor die of a semiconductor device package and materials to which the semiconductor die is sintered. For example, a semiconductor die can be sintered to a metal layer of a direct-bonded metal (DBM) substrate, such as a direct-bonded copper (DBC) substrate, rather than to a copper die attach paddle of a bare copper leadframe. The DBM substrate can include a ceramic layer (ceramic substrate), where the ceramic substrate can have a CTE that more closely matches a CTE of the semiconductor die. For instance, such ceramic substrates can have CTEs in a range of 3 to 7 ppm/K (as compared to 17 ppm/K for bare copper die attach paddles). As metal layers of DBM substrates are much thinner than those of bare copper die attach paddles, their contribution to CTE mismatch can be negligible in such implementations.

At least one technical benefit of this technical solution can be reduction or elimination of cracking of sintering material used to couple a semiconductor die with an underlying DBM substrate, e.g., as compared to a bare copper die attach paddle. At least one benefit of this technical solution is the prevention or reduction of degradation of thermal performance and/or electrical performance due to thermal cycling of a semiconductor device package, where such thermal cycling can occur as a result of operation of the semiconductor device or during reliability testing.

At least one other technical solution to the aforementioned technical problem can be use of multi-gauge signal leads, such as copper signal leads, where a portion of a multi-gauge signal lead that is coupled with a corresponding semiconductor die is thinner (has a smaller gauge) than a portion of the signal lead that is used to facilitate electrical connection of the signal lead in an associated electronic system, e.g., a portion of the signal lead that is disposed outside a molding compound of the semiconductor device package. At least one technical effect of this technical solution can be reduced stress on the die and its sintering attachments (e.g., to a DBM substrate and/or to the signal lead) due to reduced thickness of the portion of the signal lead coupled with the semiconductor die. At least one benefit of this technical solution is also prevention or reduction of degradation of thermal dissipation performance and/or electrical performance resulting from elimination or reduction of cracking of sintering material.

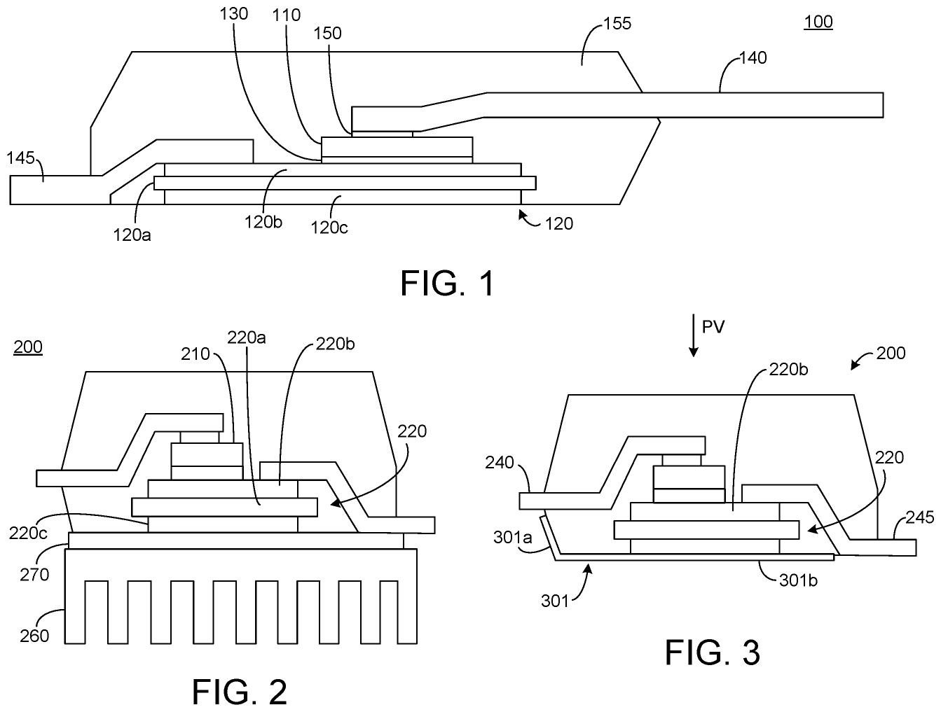

FIG. 1 is a diagram schematically illustrating a side view of an example semiconductor device package 100. In this example, a semiconductor die 110, such as a silicon carbide (SiC) semiconductor die including a discrete transistor, is sintered to a direct-bonded metal (DBM) substrate 120 using a sintering material 130, such as silver (Ag) sintering material. In some implementations, the DBM substrate 120 is a direct-bonded copper (DBC) substrate. In this example, the DBM substrate 120 includes a ceramic layer 120a (e.g., a ceramic substrate), a first metal layer 120b disposed on a first side of the ceramic layer 120a, and a second metal layer 120c disposed on an opposite side of the ceramic layer 120a. In some implementations, the first metal layer 120b and the second metal layer 120c are copper layers.

The first metal layer 120b and the second metal layer 120c can be bonded (direct-bonded) to the ceramic layer 120a, e.g., using diffusion bonding, cladding, etc. In example implementations, the ceramic layer 120a can be an aluminum oxide (Al2O3) layer with a CTE of 7 ppm/K, an aluminum nitride (AlN) layer with a CTE of 4.5 ppm/K, or a silicon nitride (Si3N4) layer with a CTE of 3 pm/K. As noted above, the metal layers 120b and 120c of the DBM substrate 120 can be significantly thinner than copper of a die attach paddle included in a bare copper leadframe. Accordingly, CTE mismatch between the DBM substrate and the SiC die can be substantially reduced as compared to prior approaches using thicker, bare copper die attach paddles with a CTE of 17 ppm/K. This reduction in CTE mismatch can improve reliability of such semiconductor device packages by preventing, or reducing the risk of cracking of sintering material used to couple the SiC die with a metal layer of the DBM substrate.

In some implementations, the DBM substrate 120 can be a direct bond copper (DBC) type structure (as noted above), a direct plating copper (DPC) type structure, or a direct bond aluminum (DBA) type structure. The DBM substrate 120 may be referred to as a heat spreader that provides single-sided cooling of the semiconductor device package 100, or other semiconductor device packages. In some implementations, the DBM substrate 120 have a thickness in a range of about 0.5 mm to about 3.0 mm. In some implementations, such as example implementations described herein, the DBM substrate 120 can be a three-layer DBM structure that includes a non-conductive layer (e.g., the ceramic layer 120a) sandwiched between a first conductive layer (e.g., the first metal layer 120b) and a second conductive layer (e.g., the second metal layer 120c). In some implementations, the non-conductive layer can serve as a thermal mass disposed between the two outer metal layers to draw in and absorb heat. The non-conductive layer may also provide electrical insulation between the first conductive layer and the second conductive layer of the DBM substrate.

In some implementations, the first conductive layer and the second conductive layer can be, or can include a metal layer (e.g., a copper layer, a copper alloy layer) that is formed on (e.g., bonded to, sputtered on, diffused onto to, heat-formed on) the non-conductive layer. The first conductive layer can be coupled to a first side of the non-conductive layer, and the second conductive layer can be coupled to a second side of the non-conductive layer. The first conductive layer can be, or can include a metal trace as a die attach pad (DAP) on which to mount a semiconductor die. In some implementations, such as described herein, the non-conductive layer can include a ceramic material, e.g., silicon nitride (Si3N4) or aluminum oxide (Al2O3). The first conductive layer or the second conductive layer can be referred to as an upper conductive layer or as a lower conductive layer depending on the orientation of the device.

In the example of FIG. 1, the semiconductor device package 100 can include respective signal leads for electrical connection to source, source sense and gate terminals of a discrete field-effect-transistor (FET) of the semiconductor die 110. In this view, only a single signal lead (signal lead 140) is shown, as other signal leads are obscured by the signal lead 140 in the example of FIG. 1. In some implementations, the signal lead 140 can be coupled with the semiconductor die 110 via direct-lead attachment (DLA), e.g., using sintering material 150, such as Ag sintering material. In some implementations, wire bonds can be used for electrically coupling respective signal leads to gate and source sense connections of a transistor of the semiconductor die 110, while DLA via sintering is used for electrically coupling a source signal lead with the transistor.

The semiconductor device package 100 of FIG. 1 also includes a signal lead 145, which can be welded (e.g., laser welded, ultrasonically welded, etc.) to the first metal layer 120b. In this example, the signal lead 145 can be electrically coupled to a drain terminal of a transistor of the semiconductor die 110 via the first metal layer 120b. Such approaches can reduce thermal stresses induced during assembly manufacturing process for the semiconductor device package 100, such as compared to performing a sintering or soldering operation for attachment of the signal lead 145.

The semiconductor device package 100 further includes a molding compound 155, which can be an epoxy molding compound that is applied by injection, molding, transfer molding, or other molding operation. As shown in FIG. 1, the molding compound 155 can encapsulate or partially encapsulate other elements of the semiconductor device package 100. For instance, in the example of FIG. 1, the molding compound 155 encapsulates the semiconductor die 110, the ceramic layer 120a, the first metal layer 120b, the sintering material 130, and the sintering material 150. The molding compound 155 also partially encapsulates the second metal layer 120c, the signal lead 140 and the signal lead 145. As shown in FIG. 1, a surface of the second metal layer 120c is exposed through the molding compound 155. Also respective first portions of the signal lead 140 and the signal lead 145 are disposed (encapsulated) in the molding compound 155, while respective second portions of the signal lead 140 and the signal lead 145 are disposed outside the molding compound 155 (e.g., for electrical connection in a corresponding electronic system).

As shown in FIG. 1, the semiconductor die 110, the signal lead 140 and the signal lead 145 are disposed on a same side of the DBM substrate 120, e.g. on a top side of the 120 in the view of FIG. 1. In prior implementations of semiconductor device package assembly, such as those including discrete transistors, drain signal leads (e.g., as compared to signal lead 145 in the semiconductor device package 100) are disposed on an opposite side of a die attach paddle (e.g., copper die attach paddle) from a semiconductor die and a source signal lead (e.g., as compared to the signal lead 140 of the semiconductor device package 100).

The semiconductor device package 100 of FIG. 1 is shown by way of example and for purposes of illustration. In some implementations, elements of the semiconductor device package 100 can have different sizes and/or dimensions. For instance, the different portions of the signal leads 140 and 145 can have different thickness arrangements. In some implementations, the portion of the signal lead 145 disposed outside the molding compound 155, the portion of the signal lead 145 coupled with the first metal layer 120b, and the connecting portion between them can have a same thickness, while in other implementations, those thicknesses can be different thicknesses. Likewise, in some implementations, the portion of the signal lead 140 disposed outside the molding compound 155, the portion of the signal lead 140 coupled with the semiconductor die 110, and the connecting portion between them can have a same thickness, while in other implementations, those thicknesses can be different thicknesses.

FIG. 2 is a diagram schematically illustrating a side view of another example semiconductor device package 200 with an attached heatsink 260. In this example, the semiconductor device package 200 can be an implementation of the semiconductor device package 100. In prior implementations, multiple layers of thermal interface material (TIM), as well as an electrical isolation layer are used to attach a heat sink to a surface of the copper die attach paddle (e.g., to a surface of a die attach paddle that is opposite a surface on which the semiconductor die is disposed). Such arrangements can reduce thermal conductivity due to an aggregate thermal resistance of the TIM layers and the electrical isolation layer.

In the example of FIG. 2, the heatsink 260 is coupled with a metal layer 220c of a DBM substrate 220 of the semiconductor device package 200 via a single layer of thermally and electrically conductive material 270, which can be sintering material, solder material (e.g., lead-free solder), or other material. In this example, a ceramic layer 220a of the DBM substrate 220 provides electrical isolation between the heatsink 260 and a semiconductor die 210. Due to elimination of an isolation layer and/or TIM material, such an arrangement can increase thermal conductivity between the semiconductor die and the heat sink, as compared to prior implementations. By way of example, thermal conductivity of TIM is 2-3 watts per meter-Kelvin (W/mK), thermal conductivity of solder is 50 W/mK, and thermal conductivity of sintering material is >=100 W/mK. Accordingly, example implementations, such as the example of FIG. 2, can have thermal conductivities that are 30 times greater (or more) than those of prior approaches, which can further reduce mechanical stresses associated with thermal cycling.

FIG. 3 is a diagram schematically illustrating an example drain-to-source creepage path 301 of the semiconductor device package 200 of FIG. 2. That is, FIG. 3 illustrates a creepage distance between a drain signal lead 245 and a source signal lead 240 of the semiconductor device package 200, e.g., a package including a discrete SiC field-effect transistor. The total creepage distance of the example of FIG. 3 is a sum of a distance of path 301a and a distance of a path 301b, which can be larger than a creepage distance of prior semiconductor device packages. For instance, in prior semiconductor device packages, a die attach paddle can have a first surface coupled with a drain of a discrete FET and a second, opposite surface exposed through an epoxy molding compound (e.g., for coupling with a heat sink). Such an arrangement results in a significantly shorter distance for a portion of a creepage distance path than the path 301b in the example of FIG. 3. Accordingly, the example of FIG. 3 can increase creepage resistance (by increasing creepage distance) and, as a result, reduce current leakage (e.g., drain-to-source leakage) as compared to previous implementations.

Furthermore, in implementations such as the example of FIG. 3, an area of the metal layer 220b of the DBM substrate 220 can be increased, e.g., approximately 15% in an example implementation, as compared to die attach paddle area in prior approaches. This area increase can improve thermal dissipation efficiency, without affecting creepage resistance or leakage. In some implementations, such as the example of FIG. 3 (as well as FIGS. 1 and 2), signal leads for source, gate and source sense, e.g., of a discrete SiC FET, can be included in a single-gauge leadframe, e.g., a leadframe of uniform thickness, which can reduce associated leadframe material costs as compared to prior approaches, as a thicker, die attach paddle is omitted.

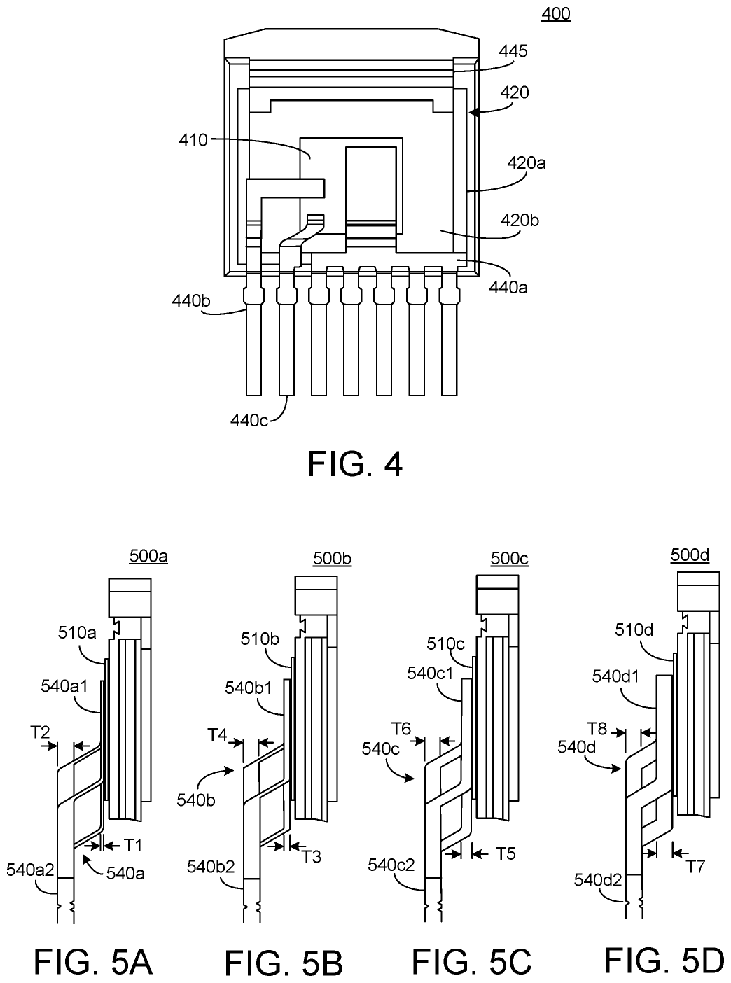

FIG. 4 is a diagram illustrating an example semiconductor device package 400, which can be an implementation of the semiconductor device packages of FIGS. 1 to 3. For purposes of illustration, a molding compound is omitted in the example of FIG. 4. As compared to the side views of FIGS. 1 to 3, the view of FIG. 4 is a plan view, e.g., along a direction indicated by the arrow PV in FIG. 3.

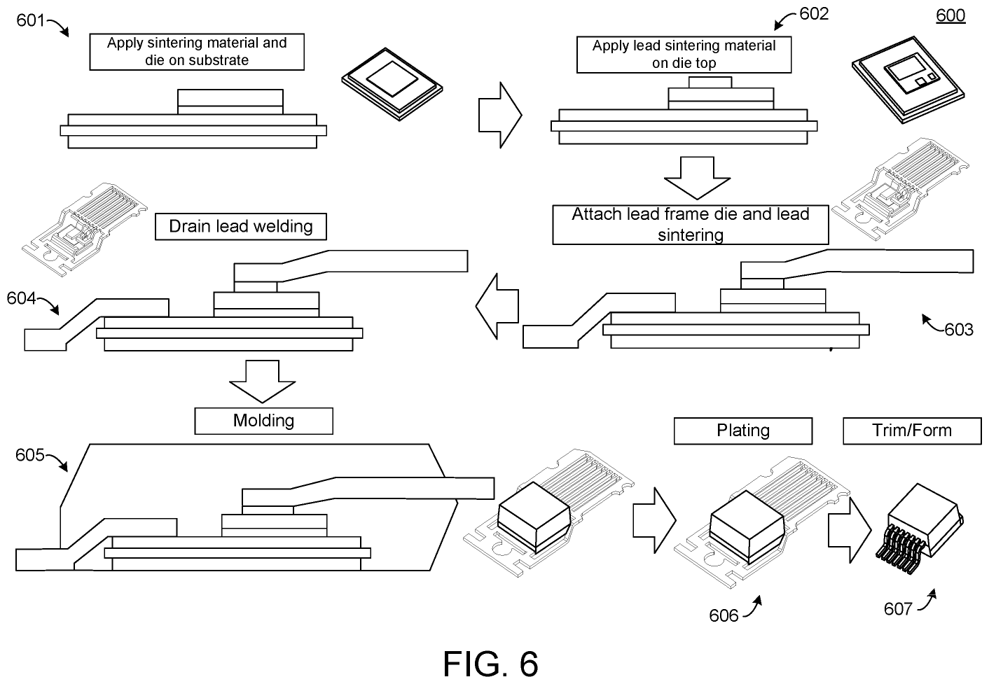

The semiconductor device package 400 includes a DBM substrate 420, with a metal layer 420b disposed on a surface of a ceramic layer 420a. A second metal layer of the DBM substrate 420 (on an opposite or bottom surface of the ceramic layer 420a is not visible in FIG. 4. The semiconductor device package 400 further includes a semiconductor die 410 (e.g., including a discrete FET transistor) disposed on the metal layer 420b, a source signal lead 440a coupled with the semiconductor die 410, a gate signal lead 440b coupled with the semiconductor die 410, a source sense signal lead 440c coupled with the semiconductor die 410, and a drain signal lead 445 coupled with the metal layer 420b. In some implementations, the semiconductor die 410 can be sintered to the metal layer 420b, and the signal leads 440a to 440c can be sintered to the semiconductor die 410. In some implementations, such as in the example of FIG. 6 discussed below, these sintering connections can be made using a single sintering operation (e.g., one-time sintering), which can reduce thermal stresses on the semiconductor device package 400 during assembly manufacturing, e.g., as compared to performing multiple sintering operations. In some implementations, the drain signal lead 445 can be welded to the metal layer 420b, e.g., using laser welding, ultrasonic welding, or other welding processes, which can also reduce thermal stresses on the semiconductor device package 400 during manufacturing, as compared to performing an additional sintering operation or a solder reflow operation for coupling the drain signal lead 445 with the metal layer 420b.

FIGS. 5A to 5D are diagrams illustrating example signal leads that can be included in a semiconductor device package. For instance, FIGS. 5A to 5C illustrate examples of dual-gauge signal leads, while FIG. 5D illustrates an example of single-gauge signal leads. As shown in FIG. 5A, a signal lead 540a of a semiconductor device package 500a includes a portion 540a1 with a thickness T1 and a portion 540a2 with a thickness T2. The thickness T2 is greater than the thickness T1. In some implementations, the thickness T2 can be at least 5 times the thickness T1. For instance, in an example implementation, the thickness T1 can be 0.1 millimeters (mm), and the thickness T2 can be 0.5 mm. As shown in FIG. 5A, the portion 540al of the signal lead 540a can be coupled with a semiconductor die 510a, e.g., sintered to a terminal (source, gate, or source sense) of a transistor included in the semiconductor die 510a. The portion 540a2 can be disposed outside a molding compound of the semiconductor device package 500a and used to facilitate electrical connection of the semiconductor die 510a of the semiconductor device package 500a in a corresponding electrical system.

Similar to FIG. 5A, in FIG. 5B, a signal lead 540b of a semiconductor device package 500b includes a portion 540b1 with a thickness T3 and a portion 540b2 with a thickness T4. The thickness T4 is greater than the thickness T3. In some implementations, the thickness T4 can be at least 2.5 times the thickness T3. For instance, in an example implementation, the thickness T3 can be 0.2 mm, and the thickness T4 can be 0.5 mm. As shown in FIG. 5B, the portion 540b1 of the signal lead 540b can be coupled with a semiconductor die 510b, e.g., sintered to a terminal (source, gate, or source sense) of a transistor included in the semiconductor die 510b. The portion 540b2 can be disposed outside a molding compound of the semiconductor device package 500b and used to facilitate electrical connection of the semiconductor die 510b of the semiconductor device package 500b in a corresponding electrical system.

Similar to FIGS. 5A and 5B, in FIG. 5C, a signal lead 540c of a semiconductor device package 500c includes a portion 540cl with a thickness T5 and a portion 540c2 with a thickness T6. The thickness T6 is greater than the thickness T5. In some implementations, the thickness T6 can be at least 1.7 times the thickness T5. For instance, in an example implementation, the thickness T5 can be 0.3 mm, and the thickness T6 can be 0.5 mm. As shown in FIG. 5C, the portion 540cl of the signal lead 540c can be coupled with a semiconductor die 510c, e.g., sintered to a terminal (source, gate, or source sense) of a transistor included in the semiconductor die 510c. The portion 540c2 can be disposed outside a molding compound of the semiconductor device package 500c and used to facilitate electrical connection of the semiconductor die 510c of the semiconductor device package 500c in a corresponding electrical system.

In FIG. 5D, a signal lead 540d of a semiconductor device package 500d includes a portion 540d1 with a thickness T7 and a portion 540d2 with a thickness T8. In this example, the thickness T8 is equal to the thickness T7. That is, the signal lead 540d can be referred to as being a single-gauge signal lead, as compared to the dual-gauge signal leads 540a, 540b and 540 of FIGS. 5A to 5C. As shown in FIG. 5D, the portion 540d1 of the signal lead 540d can be coupled with a semiconductor die 510d, e.g., sintered to a terminal (source, gate, or source sense) of a transistor included in the semiconductor die 510d. The portion 540d2 can be disposed outside a molding compound of the semiconductor device package 500d and used to facilitate electrical connection of the semiconductor die 510d of the semiconductor device package 500d in a corresponding electrical system.

In some implementations, a semiconductor device package can include signal leads with different thicknesses for a portion connected to a semiconductor die included in the package. For instance, in an example implementation, a semiconductor device package could include a combination of signal leads 540a, 540b,540c or 540d, where the particular signal lead used for a given terminal of a corresponding semiconductor die can be selected based on current and/or voltage requirements for the given terminal. As an example, in a semiconductor device package, such as the semiconductor device package 400 of FIG. 4, a signal lead for a source terminal connection could be the signal lead 540d of FIG. 5D, a signal lead for a gate terminal connection could be the signal lead 540a of FIG. 5A, and a signal lead for a source sense terminal connection could be the signal lead 540c of the FIG. 5C. Of course, other combinations are possible and will depend on the particular implementation.

Use of multi-gauge signal leads, such the signal leads 540a, 540b and 540c can reduce stresses due to CTE mismatch between the signal leads and the corresponding semiconductor die (due to reduced thickness of portions 540a1, 540b1 and 540cl), which can prevent cracking of sintering material used to couple the signal leads to the semiconductor die. Also, use of multi-gauge signal leads can reduce an amount of copper material used for producing a leadframe, which can reduce associated material costs.

FIG. 6 is a diagram illustrating an example manufacturing process 600 for producing a semiconductor device package, such as semiconductor device package implementations described herein. In the manufacturing process 600, at operation 601, sintering material is applied to (disposed on) a metal layer of a substrate, such as a DBM substrate, and a semiconductor die, such as a SiC discrete FET semiconductor die, is disposed on the sintering material. At operation 602, the manufacturing process 600 includes applying (disposing) sintering material for source, gate and source sense signal leads on a surface of the semiconductor die (e.g., an opposite surface from the side disposed on the sintering material of operation 601). At operation 603, the manufacturing process 600 includes attaching a leadframe to the structure of operation 602 and performing a sintering operation to couple (sinter) the semiconductor die to the substrate, and to sinter the source, gate and source sense signal leads to the semiconductor die. At operation 604, the manufacturing process 600 includes welding a drain signal lead to the metal layer of the substrate. At operation 605, the manufacturing process 600 includes molding the semiconductor device package to encapsulate and/or partially encapsulate elements of the structure of operation 604. At operation 606, the manufacturing process 600 includes plating exposed portions of the signal lead, e.g., respective portions of the signal leads disposed outside the molding compound. At operation 607, the manufacturing process 600 includes trimming the leadframe, e.g., to remove tie bars used to secure the signal leads in position during operations 603 to 605. Operation 607 further include forming the signal leads for a given semiconductor device package configuration.

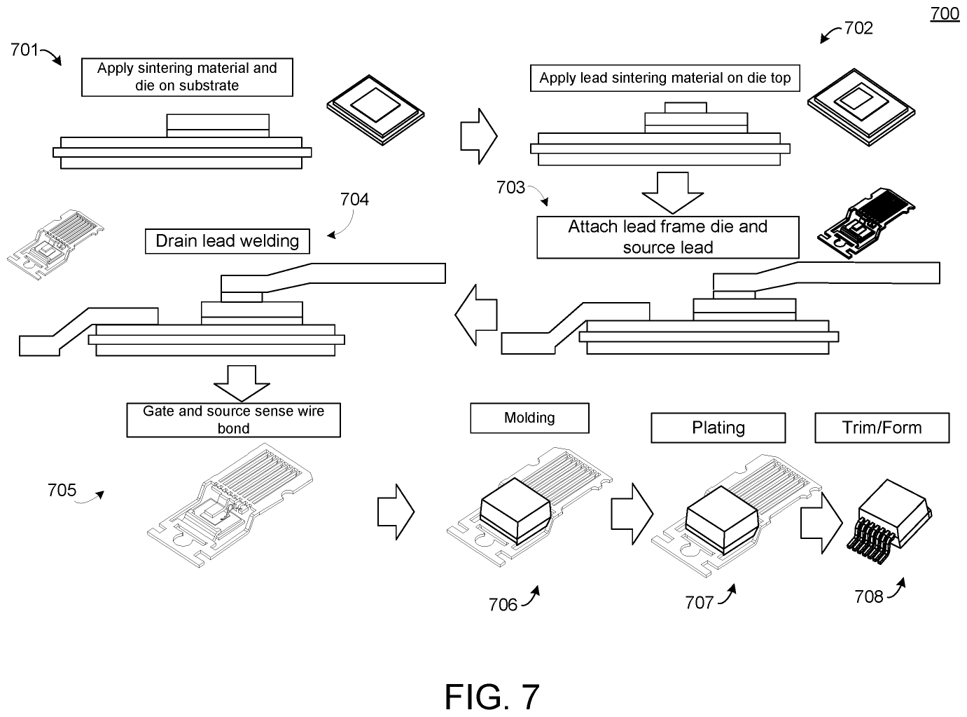

FIG. 7 is a diagram illustrating another example manufacturing process 700 for producing a semiconductor device package, such as semiconductor device package implementations described herein. In the manufacturing process 700, at operation 701, sintering material is applied to (disposed on) a metal layer of a substrate, such as a DBM substrate, and a semiconductor die, such as a SiC discrete FET semiconductor die, is disposed on the sintering material. At operation 702, the manufacturing process 700 includes applying (disposing) sintering material for a source signal lead on a surface of the semiconductor die (e.g., an opposite surface from the side disposed on the sintering material of operation 701). At operation 703, the manufacturing process 700 includes attaching a leadframe to the structure of operation 702 and performing a sintering operation to couple (sinter) the semiconductor die to the substrate, and to sinter the source signal lead to the semiconductor die. At operation 704, the manufacturing process 700 includes welding a drain signal lead to the metal layer of the substrate. At operation 705, the manufacturing process 700 includes forming respective wire bonds between a gate signal lead and a source sense signal lead and corresponding terminal (bond pads) of the semiconductor die. At operation 706, the manufacturing process 700 includes molding the semiconductor device package to encapsulate and/or partially encapsulate elements of the structure of operation 705. At operation 707, the manufacturing process 700 includes plating exposed portions of the signal lead, e.g., respective portions of the signal leads disposed outside the molding compound. At operation 708, the manufacturing process 700 includes trimming the leadframe, e.g., to remove tie bars used to secure the signal leads in position during operations 703 to 706. Operation 708 further include forming the signal leads for a given semiconductor device package configuration.

In a general aspect, a semiconductor device package includes a ceramic substrate having a first surface and a second surface opposite the first surface, a first metal layer disposed on the first surface of the ceramic substrate, a second metal layer disposed on the second surface of the ceramic substrate, and a semiconductor die having a first surface and a second surface opposite the first surface. The first surface of the semiconductor die is coupled with the first metal layer via first sintering material. The semiconductor device package also includes a first signal lead coupled with the second surface of the semiconductor die via second sintering material, a second signal lead coupled with the second surface of the semiconductor die via third sintering material; and a third signal lead coupled with the first metal layer via a weld.

Implementations can include one or more of the following features, alone or in combination. For example, the semiconductor device package can include a fourth signal lead coupled with the semiconductor die via fourth sintering material.

The semiconductor die can include a power transistor. The first signal lead can be electrically coupled, via the second sintering material, with a source terminal of the power transistor. The second signal lead can be electrically coupled, via the third sintering material, with a gate terminal of the power transistor. The third signal lead can be electrically coupled, via the first metal layer and the first sintering material, with a drain terminal of the power transistor. The fourth signal lead can be electrically coupled, via the fourth sintering material, with a source sense terminal of the power transistor.

The semiconductor device package can include a molding compound. The molding compound can encapsulate the semiconductor die, the first metal layer, and the ceramic substrate. The molding compound can partially encapsulate the second metal layer, such that a surface of the second metal layer is exposed through the molding compound, and partially encapsulating the first signal lead, the second signal lead and the third signal lead.

The first signal lead can include a first portion and a second portion. The first portion can be coupled with the semiconductor die and encapsulated in the molding compound. The first portion can have a first thickness. The second portion can be outside the molding compound. The second portion can have a second thickness greater than the first thickness.

The second signal lead can include a first portion and a second portion. The first portion of the second signal lead can be coupled with the semiconductor die and encapsulated in the molding compound. The first portion of the second signal lead can have a third thickness. The second portion of the second signal lead can be outside the molding compound. The second portion of the second signal lead can have a fourth thickness greater than the third thickness.

The third signal lead can include a first portion and a second portion. The first portion of the third signal lead can be coupled with the semiconductor die and encapsulated in the molding compound. The first portion of the third signal lead can have a fifth thickness. The second portion of the third signal lead can be outside the molding compound. The second portion of the second signal lead can have a sixth thickness greater than the fifth thickness.

The first thickness, the third thickness and the fifth thickness can be equal. The second thickness, the fourth thickness and the sixth thickness can be equal.

The third thickness and the fifth thickness can be equal and less than the first thickness.

The first thickness, the third thickness and the fifth thickness can be different thicknesses.

The ceramic substrate can electrically isolate the first metal layer from the second metal layer.

In another general aspect, a semiconductor device package includes a ceramic substrate having a first surface and a second surface opposite the first surface, a first metal layer disposed on the first surface of the ceramic substrate, a second metal layer disposed on the second surface of the ceramic substrate, and a semiconductor die having a first surface and a second surface opposite the first surface. The first surface of the semiconductor die is coupled with the first metal layer via first sintering material. The semiconductor device package also includes a first signal lead coupled with the second surface of the semiconductor die via second sintering material, a second signal lead coupled with the second surface of the semiconductor die via a first bond wire, and a third signal lead coupled with the first metal layer via a weld.

Implementations can include one or more of the following features, alone or in combination. For example, the semiconductor device package can include a fourth signal lead coupled with the semiconductor die via a second bond wire.

The semiconductor device package can include a molding compound. The molding compound can encapsulate the semiconductor die, the first bond wire, the first metal layer, and the ceramic substrate. The molding compound can partially encapsulate the second metal layer, such that a surface of the second metal layer is exposed through the molding compound; and partially encapsulating the first signal lead, the second signal lead, and the third signal lead.

The first signal lead can include a first portion and a second portion. The first portion can be coupled with the semiconductor die and encapsulated in the molding compound. The first portion can have a first thickness. The second portion can be outside the molding compound. The second portion can have a second thickness greater than the first thickness.

In another general aspect, a method for producing a semiconductor device package includes disposing first sintering material on a metal layer, the metal layer being disposed on a ceramic substrate. The method also includes disposing a first surface of a semiconductor die on the first sintering material, and disposing second sintering material on a second surface of the semiconductor die, the second surface being opposite the first surface. The method further includes disposing a first signal lead on the second sintering material; performing a sintering operation to couple the first surface of the semiconductor die with the metal layer and to couple the first signal lead to the second surface of the semiconductor die. The method also further includes welding a second signal lead to the metal layer.

Implementations can include one or more of the following features or aspects, alone of in combination. For example, the method can include, before performing the sintering operation, disposing third sintering material on the second surface of the semiconductor die, and disposing a third signal lead on the third sintering material. The sintering operation can further couple the third signal lead with the second surface of the semiconductor die.

The method can include, before performing the sintering operation, disposing fourth sintering material on the second surface of the semiconductor die, and disposing a fourth signal lead on the fourth sintering material. The sintering operation can further couple the fourth signal lead with the second surface of the semiconductor die.

The method can include, after welding the second signal lead to the metal layer, forming a first wire bond from a third signal lead to the second surface of the semiconductor die.

The method can include, after forming the first wire bond, forming a second wire bond from a fourth signal lead to the second surface of the semiconductor die.

In some aspects, the techniques described herein relate to a method, the metal layer is a first metal layer, the method further including performing an encapsulation molding process to: encapsulate the semiconductor die, the first metal layer, and the ceramic substrate in a molding compound; partially encapsulate a second metal layer disposed on a surface of the ceramic substrate opposite the first metal layer such that a surface of the second metal layer is exposed through the molding compound; and partially encapsulate the first signal lead, and the second signal lead.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device package comprising:
a ceramic substrate having a first surface and a second surface opposite the first surface;
a first metal layer disposed on the first surface of the ceramic substrate;
a second metal layer disposed on the second surface of the ceramic substrate;
a semiconductor die having a first surface and a second surface opposite the first surface, the first surface of the semiconductor die being coupled with the first metal layer via first sintering material;
a first signal lead coupled with the second surface of the semiconductor die via second sintering material;
a second signal lead coupled with the second surface of the semiconductor die via third sintering material; and
a third signal lead coupled with the first metal layer via a weld.

2. The semiconductor device package of claim 1, further comprising:
a fourth signal lead coupled with the semiconductor die via fourth sintering material.

3. The semiconductor device package of claim 2, wherein:
the semiconductor die includes a power transistor;
the first signal lead is electrically coupled, via the second sintering material, with a source terminal of the power transistor;
the second signal lead is electrically coupled, via the third sintering material, with a gate terminal of the power transistor;
the third signal lead is electrically coupled, via the first metal layer and the first sintering material, with a drain terminal of the power transistor; and
the fourth signal lead is electrically coupled, via the fourth sintering material, with a source sense terminal of the power transistor.

4. The semiconductor device package of claim 1, further comprising a molding compound, the molding compound:
encapsulating the semiconductor die, the first metal layer, and the ceramic substrate;
partially encapsulating the second metal layer, such that a surface of the second metal layer is exposed through the molding compound; and
partially encapsulating the first signal lead, the second signal lead and the third signal lead.

5. The semiconductor device package of claim 4, wherein the first signal lead includes a first portion and a second portion, the first portion being coupled with the semiconductor die and encapsulated in the molding compound, the first portion having a first thickness, the second portion being outside the molding compound, and the second portion having a second thickness greater than the first thickness.

6. The semiconductor device package of claim 4, wherein:
the first signal lead includes a first portion and a second portion, the first portion of the first signal lead being coupled with the semiconductor die and encapsulated in the molding compound, the first portion of the first signal lead having a first thickness, the second portion of the first signal lead being outside the molding compound, and the second portion of the first signal lead having a second thickness greater than the first thickness;
the second signal lead includes a first portion and a second portion, the first portion of the second signal lead being coupled with the semiconductor die and encapsulated in the molding compound, the first portion of the second signal lead having a third thickness, the second portion of the second signal lead being outside the molding compound, and the second portion of the second signal lead having a fourth thickness greater than the third thickness; and
the third signal lead includes a first portion and a second portion, the first portion of the third signal lead being coupled with the semiconductor die and encapsulated in the molding compound, the first portion of the third signal lead having a fifth thickness, the second portion of the third signal lead being outside the molding compound, and the second portion of the second signal lead having a sixth thickness greater than the fifth thickness.

7. The semiconductor device package of claim 6, wherein:
the first thickness, the third thickness and the fifth thickness are equal; and
the second thickness, the fourth thickness and the sixth thickness are equal.

8. The semiconductor device package of claim 6, wherein:
the third thickness and the fifth thickness are equal and less than the first thickness; and
the second thickness, the fourth thickness and the sixth thickness are equal.

9. The semiconductor device package of claim 6, wherein:
the first thickness, the third thickness and the fifth thickness are different thicknesses; and
the second thickness, the fourth thickness and the sixth thickness are equal.

10. The semiconductor device package of claim 1, wherein the ceramic substrate electrically isolates the first metal layer from the second metal layer.

11. A semiconductor device package comprising:
a ceramic substrate having a first surface and a second surface opposite the first surface;
a first metal layer disposed on the first surface of the ceramic substrate;
a second metal layer disposed on the second surface of the ceramic substrate;
a semiconductor die having a first surface and a second surface opposite the first surface, the first surface of the semiconductor die being coupled with the first metal layer via first sintering material;
a first signal lead coupled with the second surface of the semiconductor die via second sintering material;
a second signal lead coupled with the second surface of the semiconductor die via a first bond wire; and
a third signal lead coupled with the first metal layer via a weld.

12. The semiconductor device package of claim 11, further comprising:
a fourth signal lead coupled with the semiconductor die via a second bond wire.

13. The semiconductor device package of claim 11, further comprising a molding compound, the molding compound:
encapsulating the semiconductor die, the first bond wire, the first metal layer, and the ceramic substrate;
partially encapsulating the second metal layer, such that a surface of the second metal layer is exposed through the molding compound; and
partially encapsulating the first signal lead, the second signal lead, and the third signal lead.

14. The semiconductor device package of claim 13, wherein the first signal lead includes a first portion and a second portion, the first portion being coupled with the semiconductor die and encapsulated in the molding compound, the first portion having a first thickness, the second portion being outside the molding compound, the second portion having a second thickness greater than the first thickness.

15. A method for producing a semiconductor device package, the method comprising:
disposing first sintering material on a metal layer, the metal layer being disposed on a ceramic substrate;
disposing a first surface of a semiconductor die on the first sintering material;
disposing second sintering material on a second surface of the semiconductor die, the second surface being opposite the first surface;
disposing a first signal lead on the second sintering material;
performing a sintering operation to couple the first surface of the semiconductor die with the metal layer and to couple the first signal lead to the second surface of the semiconductor die; and
welding a second signal lead to the metal layer.

16. The method of claim 15, further comprising, before performing the sintering operation:
disposing third sintering material on the second surface of the semiconductor die; and
disposing a third signal lead on the third sintering material,
the sintering operation further coupling the third signal lead with the second surface of the semiconductor die.

17. The method of claim 16, further comprising, before performing the sintering operation:
disposing fourth sintering material on the second surface of the semiconductor die; and
disposing a fourth signal lead on the fourth sintering material,
the sintering operation further coupling the fourth signal lead with the second surface of the semiconductor die.

18. The method of claim 15, further comprising, after welding the second signal lead to the metal layer:
forming a first wire bond from a third signal lead to the second surface of the semiconductor die.

19. The method of claim 18, further comprising, after forming the first wire bond:
forming a second wire bond from a fourth signal lead to the second surface of the semiconductor die.

20. The method of claim 15, wherein the metal layer is a first metal layer, the method further comprising performing an encapsulation molding process to:
encapsulate the semiconductor die, the first metal layer, and the ceramic substrate in a molding compound;
partially encapsulate a second metal layer disposed on a surface of the ceramic substrate opposite the first metal layer such that a surface of the second metal layer is exposed through the molding compound; and
partially encapsulate the first signal lead, and the second signal lead.
